(19) United States
(12) Patent Application Publication
(10) Pub. No.: US 2014/0091330 A1
(43) Pub. Date: Apr. 3, 2014

(54) LED PACKAGE STRUCTURE WITH TRANSPARENT ELECTRODES

(71) Applicants: Ming-Hung CHEN, Zhudong Town (TW); Ching-Jen Pan, Zhudong Town (TW); Shih-Chang Shei, Zhudong Town (TW)

(72) Inventors: Ming-Hung CHEN, Zhudong Town (TW); Ching-Jen Pan, Zhudong Town (TW); Shih-Chang Shei, Zhudong Town (TW)

(73) Assignee: HELIO OPTOELECTRONICS CORPORATION

(21) Appl. No.: 13/633,671

(22) Filed: Oct. 2, 2012

(51) Int. Cl. H01L 33/42

(52) U.S. Cl. 257/88; 257/E33.064

(57) ABSTRACT

The present invention discloses a LED package structure with transparent electrodes. The electrode layers [symbol] the semiconductor layers inside the LED chip and the protection layer are all transparent to visible and invisible lights. With the adoption of the present invention, electrodes on the LED package no longer block any part of the light emission from inside the LED.

### BACKGROUND OF THE INVENTION

1. Technical Field

The present invention relates to a light-emitting diode (LED) package structure with transparent electrodes. More particularly, the present invention relates to an LED package structure whose electrode layers and protective layers are all formed of light-permeable materials.

2. Description of Related Art

The electrode layers and electrical connection layers in the conventional LED package structures are typically formed of light-impermeable metal or semiconductor material, which however have an adverse effect on the direction and amount of light emitted by such LEDs and compromise the efficiency of light emission seriously. This is especially undesirable where a high light emission is required.

To increase the amount of light emitted by LEDs, research efforts have been directed to circuit structures and the semiconductor materials of LEDs and have produced effective solutions. Nevertheless, the light of the improved LEDs is still blocked by the electrode layers and the electrical connection layers.

Therefore, in the current stage of LED package development it is imperative to adopt a comprehensive approach to increasing light emission efficiency. This comprehensive approach should not only involve improvements on semiconductor materials and circuit structures, but also take into account the LED packaging methods and elimination of the undesirable light-blocking effect of the electrode layers and the connection layers.

### BRIEF SUMMARY OF THE INVENTION

The present invention discloses an LED package structure with transparent electrodes, in which the electrode layers and protective layers are all formed of light-permeable materials. With the implementation of the present invention, the light emitted by LEDs will no longer be blocked by the necessary electrodes or the connection layers required for making electrical connection between the LEDs, and higher light emission efficiency is thus achieved.

To attain the above objective, the present invention provides an LED package structure with transparent electrodes, wherein the LED package structure includes: a growth substrate having a first surface and a second surface, a plurality of chip units formed on the first surface, a plurality of protective layers, a plurality of first connection layers, a plurality of second connection layers, a plurality of metal pads, and a reflective layer formed on the second surface.

Implementation of the present invention at least involves the following advantageous effects:

1. The light emitted by the LED chip units will not be blocked by the electrodes or the electrical connection layers, so higher light emission efficiency than conventionally allowed is achieved.

The detailed features and advantages of the present invention will be described in detail with reference to the preferred embodiment so as to enable persons skilled in the art to gain insight into the technical disclosure of the present invention, implement the present invention accordingly, and readily understand the objectives and advantages of the present invention by perusal of the contents disclosed in the specification, the claims, and the accompanying drawings.

### BRIEF DESCRIPTION OF THE SEVERAL VIEWS OF THE DRAWINGS

FIG. 1 is a diagram of an embodiment of a light-emitting diode (LED) package structure with transparent electrodes of the present invention.

FIG. 2 is a diagram of an embodiment of a chip unit of the embodiment as described in FIG. 1.

FIG. 3 is a diagram of another embodiment of a light-emitting diode (LED) package structure with transparent electrodes of the present invention.

FIG. 4 is a diagram of an embodiment of a chip unit of the embodiment as described in FIG. 3.

### DETAILED DESCRIPTION OF THE INVENTION

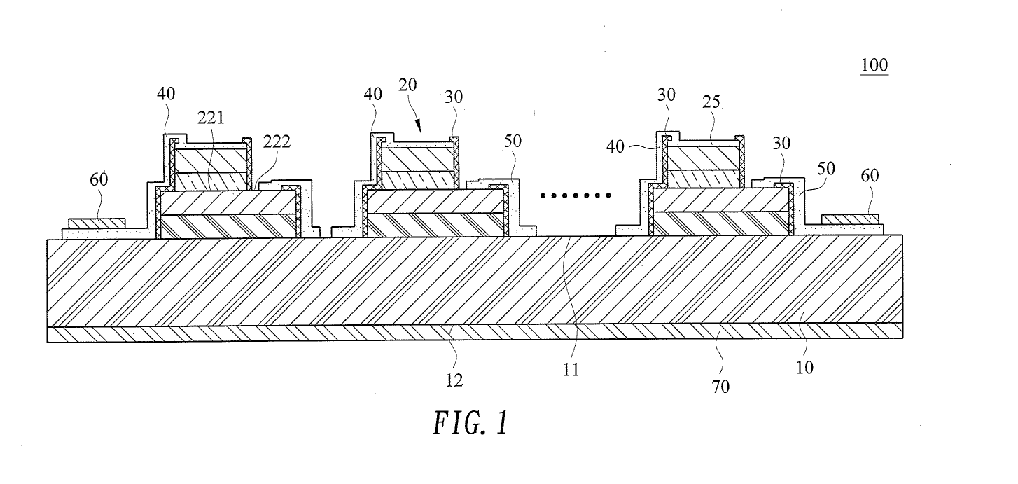

As shown in FIG. 1, an LED package structure 100 with transparent electrodes according to an embodiment of the present invention includes; a growth substrate 10 having a first surface 11 and a second surface 12, a plurality of chip units 20 formed on the first surface 11, a plurality of protective layers 30, a plurality of first connection layers 40, a plurality of second connection layers 50, a plurality of metal pads 60, and a reflective layer 70 formed on the second surface 12.

The growth substrate 10 is formed of an insulating, heat-dissipating, and light-permeable material and serves as the base plate of the LED package structure 100. The growth substrate 10 has a first surface 11 and a second surface 12.

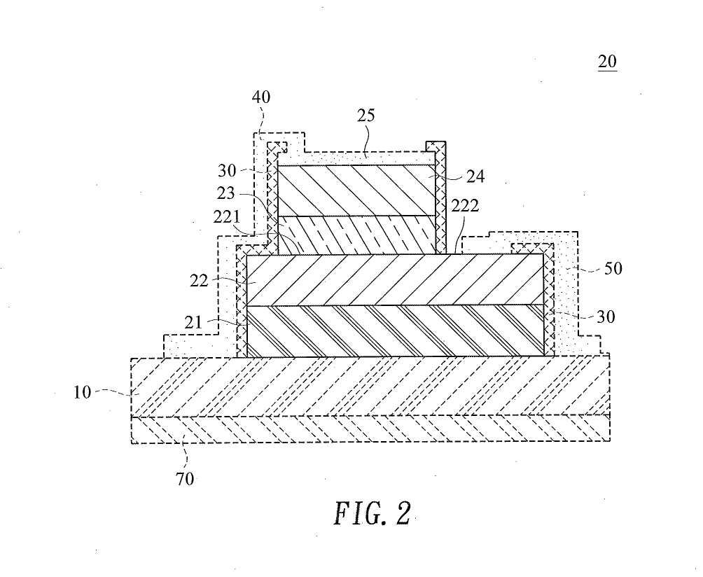

As shown in FIG. 2, one of the plural chip units 20 is formed on the first surface 11. The chip units 20 in the present embodiment of the invention are LED chips and each include: a buffer layer 21 grown on the first surface 11; a N-type semiconductor layer 22 grown on the buffer layer 21, wherein a light-emitting layer growing area 221 and an electrode connection area 222 are formed on a surface of the N-type semiconductor layer 22 and are separate from each other; a light-emitting layer 23 grown on the light-emitting layer growing area 221; a P-type semiconductor layer 24 grown on the light-emitting layer 23; and a transparent electrode layer 25 formed on the P-type semiconductor layer 24, wherein the transparent electrode layer 25 is formed of a light-permeable conductive material and is transparent to both visible and invisible light.

The plural protective layers 30 are formed of light-permeable insulating material. This light-permeable insulating material can be silicon dioxide, aluminum oxide, titanium dioxide, zinc oxide, or other light-permeable insulating materials such that the protective layers 30 are transparent to both visible and invisible light. Each protective layer 30 is formed on the periphery of one chip unit 20 and extends to the edge of the top surface of the chip unit 20. Each protective layer 30 also extends to the edge of the electrode connection area 222 of one chip unit 20.

Each of the plural first connection layers 40 extends from one transparent electrode layer 25 to the first surface 11. The first connection layers 40 are formed of a light-permeable conductive material and are transparent to both visible and invisible light. The P-type semiconductor layer 24 of each chip unit 20 is electrically connected to other chip units 20 via the corresponding transparent electrode layer 25 and the first connection layers 40.

Each of the plural second connection layers 50 extends from one electrode connection area 222 to the first surface 11. The second connection layers 50 are formed of a light-permeable conductive material and are transparent to both visible and invisible light. The N-type semiconductor layer 22 of each chip unit 20 is electrically connected to other chip units 20 via the second connection layers 50.

In the LED package structure 100 shown in FIG. 1, electrical connection between the chip units 20 is achieved by connecting in series, connecting in parallel, or connecting in series and parallel the first connection layers 40 and the second connection layers 50. To fond a structure of the chip units 20 connected in series, the first connection layer 40 connected to one chip unit 20 is electrically connected to the second connection layer 50 connected to another chip unit 20, and the same series connecting operation is performed on all the chip units 20. To form a structure of the chip units 20 connected in parallel, the first and the second connection layers 40 and 50 connected to one chip unit 20 are respectively and electrically connected to the first and, the second connection layers 40 and 50 connected to another chip unit 20, and the same parallel connecting operation is performed on all the chip units 20.

To form a structure of the chip units 20 connected in series and parallel, the series or the parallel connection methods above are partially mixed, for instance, some sub groups are formed by chip units 20 connected in series, and then these sub groups are connected in parallel; or some sub groups are formed by chip units 20 connected in parallel, and then these sub groups are connected in series.

The plural metal pads 60 are formed on the first and the second connection layers 40 and 50 located at the edges of the first surface 11. These metal pads 60 function as contacts through which the LED package structure 100 shown in FIG. 1 can make external electrical connection.

The reflective layer 70 is formed on the second surface 12. The reflective layer 70 is formed of a reflective material and serves mainly to reflect the light projected thereto from each chip unit 20, thereby increasing the total amount of light emission of each chip unit 20.

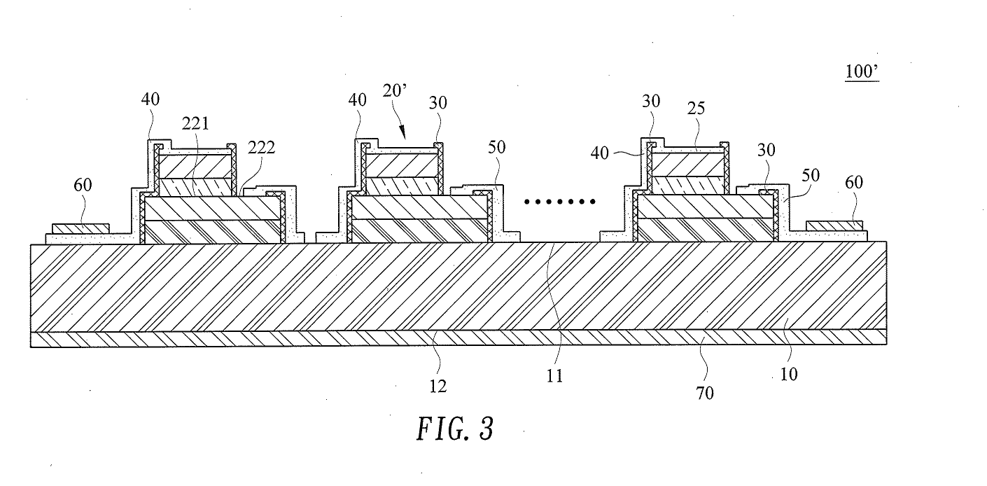

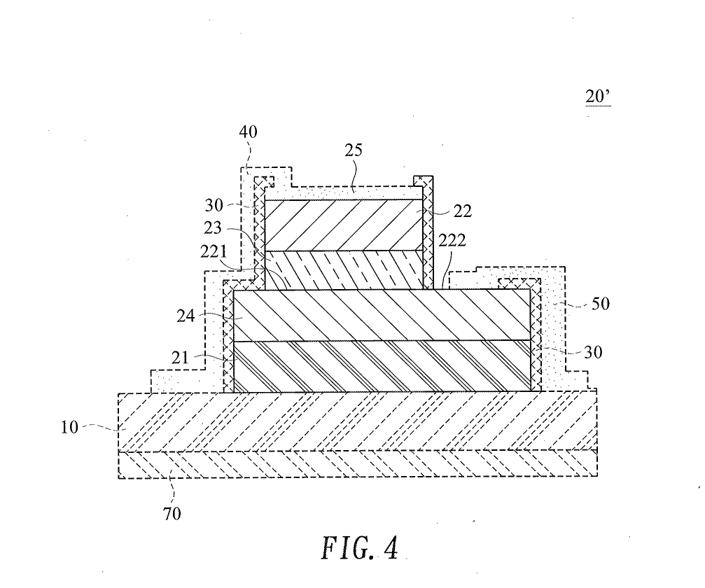

FIG. 3 shows an LED package structure 100′ with transparent electrodes according to another embodiment of the present invention. The LED package structure 100′ includes: a growth substrate 10 having a first surface 11 and a second surface 12, a plurality of chip units 20′ formed on the first surface 11, a plurality of protective layers 30, a plurality of first connection layers 40, a plurality of second connection layers 50, a plurality of metal pads 60, and a reflective layer 70 formed on the second surface 12. The LED package structure 100′ in FIG. 3 is different from the LED package structure 100 in FIG. 1 only in that the P-type semiconductor layer 24 and the N-type semiconductor layer 22 switch positions in the semiconductor manufacturing process so as to form the chip unit 20′ depicted in FIG. 4. Nonetheless, the embodiment shown in FIG. 3 has the same light emission effect as that shown FIG. 1.

The features of the present invention disclosed above by the preferred embodiment are to allow persons skilled in the art to gain insight into the contents of the present invention and implement the present invention accordingly. The preferred embodiment of the present invention should not be interpreted, as restrictive of the scope of the present invention. Hence, all equivalent modifications or amendments made to the aforesaid embodiment should fall within the scope of the appended claims.

1. A light-emitting diode (LED) package structure with transparent electrodes, comprising:
a growth substrate formed of an insulating heat-dissipating material and having a first surface and a second surface;
a plurality of chip units formed on the first surface, each said chip unit comprising: a buffer layer grown on the first surface; an N-type semiconductor layer grown on the buffer layer, wherein the N-type semiconductor layer has a surface formed with a light-emitting layer growing area and an electrode connection area separate from the light-emitting layer growing area; a light-emitting layer grown on the light-emitting layer growing area; a P-type semiconductor layer grown on the light-emitting layer; and a transparent electrode layer formed on the P-type semiconductor layer; wherein each layer of the chip units are electrically conductive;
a plurality of protective layers formed of a light-permeable conductive material, each said protective layer being formed on a periphery of a said chip unit and extending to an edge of a top surface of the chip unit, each said protective layer also extending to an edge of a said electrode connection area;
a plurality of first connection layers formed of a light-permeable conductive material, each said first connection layer extending from a said transparent electrode layer to the first surface;
a plurality of second connection layers formed of a light-permeable conductive material, each said second connection layer extending from a said electrode connection area to the first surface;
a plurality of metal pads formed on said first connection layers and said second connection layers and are located at edges of the first surface; and
a reflective layer formed on the second surface,
wherein the first connection layers of the chip units are electrically connected one of in series, in parallel, and in series and parallel with the second connection layers.

2. (canceled)

3. The LED package structure of claim 1, wherein the protective layers are formed of a light-permeable insulating material.

4. The LED package structure of claim 1, wherein the metal pads are contacts for making external electrical connection.

5. The LED package structure of claim 1, wherein the reflective layer is formed of a light reflective material.

6. A light-emitting diode (LED) package structure with transparent electrodes, comprising:
a growth substrate formed of an insulating heat-dissipating material and having a first surface and a second surface;
a plurality of chip units formed on the first surface, each said chip unit comprising: a buffer layer grown on the first surface; a P-type semiconductor layer grown on the buffer layer, wherein the P-type semiconductor layer has a surface formed with a light-emitting layer growing area and an electrode connection area separate from the light-emitting layer growing area; a light-emitting layer grown on the light-emitting layer growing area; an N-type semiconductor layer grown on the light-emitting layer; and a transparent electrode layer formed on the N-type semiconductor layer;
a plurality of protective layers formed of a light-permeable conductive material, each said protective layer being formed on a periphery of a said chip unit and extending to an edge of a top surface of the chip unit, each said protective layer also extending to an edge of a said electrode connection area;
a plurality of first connection layers formed of a light-permeable conductive material, each said first connection layer extending from a said transparent electrode layer to the first surface;
a plurality of second connection layers formed of a light-permeable conductive material, each said second connection layer extending from a said electrode connection area to the first surface;
a plurality of metal pads formed on said first connection layers and said second connection layers that are located at edges of the first surface; and
a reflective layer formed on the second surface,
wherein the first connection layers of the chip units are electrically connected one of in series, in parallel, and in series and parallel with the second connection layers.

7. (canceled)

8. The LED package structure of claim 6, wherein the protective layers are formed of light-permeable insulating material.

9. The LED package structure of claim 6, wherein the metal pads are contacts for making external electrical connection.

10. The LED package structure of claim 6, wherein the reflective layer is formed of a reflective material.
